(19) United States
(12) Patent Application Publication
(10) Pub. No.: US 2008/0061449 A1
(43) Pub. Date: Mar. 13, 2008

(54) Semiconductor Component Arrangement

(75) Inventors: Joachim Mahler, Regensburg (DE); Thomas Behrens, Wenzenbach (DE); Reimund Engl, Regensburg (DE); Khalil Hosseini, Weihmichl (DE); Stefan Landau, Wehrheim (DE); Boris Plikat, Tegernheim (DE)

Correspondence Address: INFINEON TECHNOLOGIES AG;Patent Department, MUC 11.1.507, P.O. Box 221644, Munich, 80506, omitted

(73) Assignee: INFINEON TECHNOLOGIES AG, Muenchen (DE)

(21) Appl. No.: 11/851,397

(22) Filed: Sep. 7, 2007

(30) Foreign Application Priority Data
Sep. 7, 2006 (DE) 102006042032.2

(51) Int. Cl. H01L 23/12; H01L 21/66

(52) U.S. Cl. 257/783; 438/15; 257/E23.003; 257/E21.53

(57) ABSTRACT

A semiconductor component arrangement having a semiconductor component, a mount, and an adhesive, wherein the adhesive connects the semiconductor component to the mount and the adhesive contains a marker substance. Also disclosed is a method for inspecting the connection of a semiconductor component to a mount. The semiconductor component is fixed on the mount using an adhesive, wherein the adhesive contains a marker substance, the mount with the semiconductor component is cleaned, and the mount is inspected for residues of the adhesive on the basis of radiation which is characteristic of the marker substance.

### RELATED APPLICATION

The present application claims priority to German Application No. 10 2006 042 032.2 filed 7 Sep. 2006, which is incorporated by reference herein in its entirety.

### FIELD OF THE INVENTION

The present invention relates to a semiconductor component arrangement and to a method for inspecting a semiconductor component arrangement.

### BACKGROUND OF THE INVENTION

Semiconductor components, such as integrated circuits or individual semiconductors, are generally applied on a mount. The semiconductor component is connected to the mount by means of an adhesive or a solder. A leadframe, a printed circuit board or another semiconductor component can be a mount.

It is the task of the adhesive to connect the semiconductor component fixedly and reliably to the mount. Once the mount has been provided, the adhesive is applied to the substrate. Subsequently the semiconductor component is pressed into the adhesive. The adhesive can be cured at temperatures higher than room temperature. A typical maximum curing temperature of adhesives is 200° C., for example.

In order to ensure a reliable connection of the semiconductor component to the mount, the semiconductor component can be completely embedded in the adhesive.

If a semiconductor component is mounted on a further semiconductor component or if a further electrical connection to the semiconductor component is to be established on the mount, it is preferred that the area comprising adhesive is as small as possible.

During the curing of the adhesive, constituents of the adhesive may leave the adhesive and deposit on the mount in thin layers. This behaviour is referred to as bleed-out of the adhesive. If constituents of the adhesive have bled out, this can be a sign of a lack of quality of the adhesive or it can suggest a lack of quality of the connection of the semiconductor component to the mount.

As a result of a bled-out adhesive, it is also possible that electrical connections to the mount cannot be carried out with the necessary reliability.

A possible consequence of the bleed-out of the adhesive is that the subsequently used insulating substance is not connected reliably to the mount at those locations at which the bled-out adhesive is located.

The problem of connecting a semiconductor component to a mount with the aid of an adhesive has hitherto been solved in that only adhesives whose low bleed-out behaviour was assured by their manufacturers have been used. This has the disadvantage that this characteristic of the adhesive limited the choice of useful adhesives very severely.

A check of the bleed-out behaviour of these adhesives is possible only to a very limited degree, because complicated methods of analysis are necessary in order to assess the bleed-out behaviour. A check of the bleed-out behaviour is therefore possible only in random samples. Visual detection of the adhesive film, whose thickness is often only a few nanometres, is possible only with a high outlay.

It is furthermore possible to accept the thin adhesive film spreading on the mount on account of the bleed-out. This is, however, accompanied by a number of losses in terms of quality. The quality of electrical connections between the semiconductor component and the mount cannot be reliably assured.

For the reliability of the connection of the semiconductor component on a mount to be assured, a process check is desired which ensures that the semiconductor component is connected reliably to the mount, and that the subsequent substance intended to insulate the semiconductor component from the surroundings adheres reliably on the semiconductor component and on the mount. It is furthermore desired that the applied adhesive intended to connect the semiconductor component to a mount does not impede the application of electrical contacts.

### SUMMARY OF THE INVENTION

The present invention is based on the problem of assessing the connection of a semiconductor component to a mount in a simple manner.

In one embodiment, a semiconductor component arrangement according to the invention comprises: a semiconductor component, a mount, an adhesive, wherein the adhesive connects the semiconductor component to the mount and the adhesive contains a marker substance.

A semiconductor component arrangement, which is connected to a mount using an adhesive, is then insulated from the surroundings with the aid of a substance. This is a so-called moulding compound if said insulating substance defines a shape and forms the housing. An adhesive film resulting from the bleed-out of the adhesive on the substrate generally reduces the adhesion of the moulding compound on the mount.

### BRIEF DESCRIPTION OF THE DRAWINGS

FIG. 1 shows a cross-section of an exemplary embodiment of a semiconductor component arrangement.

### DETAILED DESCRIPTION OF THE DRAWINGS

Semiconductor components, such as integrated circuits or discrete semiconductor components, are, inter alia, connected to a mount with the aid of adhesives. Subsequently the semiconductor component connected to the mount is enveloped by a further substance, whose task it is to insulate the semiconductor component from the surroundings. This enveloping substance can be a moulding compound, for example, which subsequently also gives shape to the semiconductor component arrangement. Such a semiconductor component arrangement is referred to as semiconductor in a housing. Furthermore, semiconductor components can be applied to mounts comprising further semiconductor components and other electronic components. In this case, the mount could be, for example, a printed circuit board on which the semiconductor element is applied, connected using an adhesive and subsequently insulated from the surroundings using a substance. It is similarly possible to apply a semiconductor component on another semiconductor component. This case is referred to as chip-on-chip mounting.

The admixing of a marker substance in the adhesive connecting the semiconductor component to the mount has the particular advantage that defects that occur are recognized easily by means of a simple visual check. Undesired adhesive residues can similarly be recognized by an automatic optical check. If the adhesive is cured in a thermal process, there is a risk that substances from the adhesive mixture will spread thinly on the mount. If a semiconductor component intended to be connected to the mount by means of an adhesive is pressed into the adhesive compound at high pressure, substances from the adhesive mixture can be distributed thinly on the mount. Such a thin distribution, that is to say a film-like spreading of adhesive substances, is referred to as bleed-out.

Marker substances which can be used include both organic and inorganic dyes.

The marker substance used has a proportion by mass in the adhesive of less than about 0.1% in one embodiment.

The marker substance used can be dissolved in the solvent of the adhesive.

The marker substance used can be fluorescent. The marker substance used can have a radiation intensity which is limited to a narrow frequency range.

The adhesive with a marker substance can be used to connect a semiconductor component to a further semiconductor component.

A method for inspecting the connection of a semiconductor component to a mount according to the invention comprises the step of fixing the semiconductor component on the mount using an adhesive. The adhesive contains a marker substance. The mount is inspected for residues of the adhesive after the mount with the connected semiconductor component has been cleaned. Based on the specific characteristics of the marker substance in the adhesive, it is possible to reliably recognize the residues of the adhesive.

Based on the specific characteristics of the marker substance in the adhesive, it is possible to recognize the residues of the adhesive by means of an automatic method.

On account of a high radiation intensity of the marker substance it is possible to carry out a simple and efficient process check.

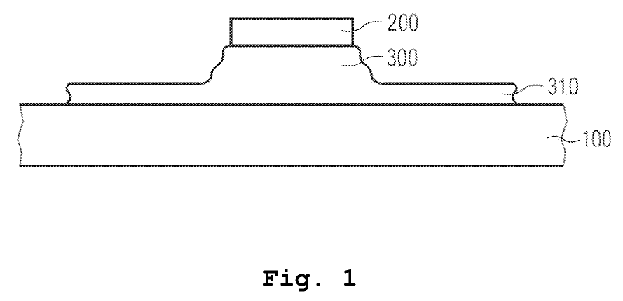

Embodiments of the invention are illustrated in detail below with reference to the attached drawings, in which FIG. 1 shows an exemplary embodiment of a semiconductor component arrangement.

FIG. 1 shows a semiconductor component 200, a mount 100, an adhesive 300 and bled-out constituents of the adhesive 310. An adhesive 300 connecting the semiconductor component 200 to the mount 100 is applied to the mount 100. Constituents of the adhesive can form a film 310 on the mount. As the adhesive contains a marker substance, the bled-out constituents of the adhesive can be easily recognized.

1. A semiconductor component arrangement comprising:
a semiconductor component;
a mount; and
an adhesive, wherein the adhesive connects the semiconductor component to the mount and comprises a marker substance.

2. A semiconductor component arrangement according to claim 1, wherein the marker substance is an organic dye.

3. A semiconductor component arrangement according to claim 1, wherein the marker substance is an inorganic dye.

4. A semiconductor component arrangement according to claim 1, wherein the marker substance in the adhesive has a proportion by mass of less than about 0.1%.

5. A semiconductor component arrangement according to claim 1, wherein the marker substance is dissolved in a solvent of the adhesive.

6. A semiconductor component arrangement according to claim 1, wherein the marker substance is admixed as a pigment in the adhesive.

7. A semiconductor component arrangement according to claim 1, wherein a radiation intensity of the marker substance of the adhesive is limited to a narrow frequency range.

8. A semiconductor component arrangement according to claim 1, wherein the mount is a further semiconductor component.

9. A method for inspecting the connection of a semiconductor component to a mount, comprising the steps of:
fixing the semiconductor component on the mount using an adhesive, wherein the adhesive comprises a marker substance; and
inspecting the mount for residues of the adhesive on the basis of radiation characteristic of the marker substance.

10. A method according to claim 9, further comprising the step of cleaning the mount with the semiconductor component before the step of inspecting.

11. A method according to claim 9, wherein the marker substance of the adhesive is an organic dye.

12. A method according to claim 9, wherein the marker substance of the adhesive is an inorganic dye.

13. A method according to claim 9, wherein the marker substance in the adhesive has a proportion by mass of less than about 0.1%.

14. A method according to claim 9, wherein a radiation intensity of the marker substance of the adhesive is limited to a narrow frequency range.

15. A method according to claim 9, wherein a connection between the semiconductor component and the mount is inspected by a visual check.

16. A method according to claim 15, wherein the connection is inspected by a visual check using a microscope.

17. A method according to claim 9, wherein a connection between the semiconductor component and the mount is inspected by an automatic method.

18. A method according to claim 15, wherein the connection is inspected using a spectral filter.

19. A method according to claim 17, wherein the connection is inspected using a spectral filter.
